(19) United States
(12) Patent Application Publication
(10) Pub. No.: US 2025/0061241 A1
(43) Pub. Date: Feb. 20, 2025

(54) SYSTEM AND METHOD OF FEDERATED COMPUTER-AIDED MODELING

(71) Applicant: TECHNION RESEARCH & DEVELOPMENT FOUNDATION LIMITED, Haifa (IL)

(72) Inventors: Rafael SACKS, Haifa (IL); Zijian WANG, Haifa (IL); Boyuan OUYANG, Haifa (IL)

(21) Appl. No.: 18/805,715

(22) Filed: Aug. 15, 2024

Related U.S. Application Data
(60) Provisional application No. 63/533,143, filed on Aug. 17, 2023.

(51) Int. Cl. G06F 30/13; G06F 30/27

(52) U.S. Cl. CPC G06F 30/13; G06F 30/27

(57) ABSTRACT

The present invention relates generally to the technological field of computer-aided design and modeling. In the general aspect, the invention may be directed to a method of federated computer-aided modeling of an object, by at least one processor, the method including: obtaining a plurality of sub-models, complementary representing the object, wherein each sub-model consists of one or more structural elements defined by parameters thereof; for each sub-model, generating a sub-graph representation, having said structural elements and parameters thereof represented as semantic triples; analyzing said semantic triples taken from different sub-graph representations to detect interrelations therebetween; instantiating semantic connections between the generated sub-graph representations, based on detected interrelations, thereby obtaining a meta-graph representation of a model of the object; and developing the model of the object, based on the obtained meta-graph representation.

### CROSS REFERENCE TO RELATED APPLICATIONS

This application claims the benefit of priority of U.S. Provisional Patent Application No. 63/533,143, filed Aug. 17, 2023, the contents of which are all incorporated herein by reference in their entirety.

### FIELD OF THE INVENTION

The present invention relates generally to the technological field of computer-aided design and modeling. More specifically, the present invention relates to aspects of federated (or collaborative) computer-aided design and modeling improvement.

### BACKGROUND OF THE INVENTION

Nowadays, computer-aided modeling is ubiquitously applied within various engineering and designing disciplines, e.g., architectural, mechanical, and electronic. The process of modeling usually is characterized by a complex nature which necessitates an incorporation of various collaborative and federated methods.

In particular, the Architecture, Engineering and Construction (AEC) industry is characterized by its fragmented nature in the sense that numerous stakeholders with diverse specialties are involved throughout the lifecycle of a building project. This necessitates close collaboration between different design entities, each with its own methods of working and preferences for Building Information Modeling (BIM) authoring tools, during the design phase of projects to deliver a holistic building design. Effective and efficient communications between design teams are key to the success of project delivery. The communication process often involves extensive exchange of design sub-models, e.g., models of specific parts of the complex object, complementary representing the object and usually pertaining to separate engineering and designing disciplines. The collaboration is built around evolving the federated discipline sub-models while maintaining their consistency throughout the process, until the sub-models are mature enough to be constructed, thereby forming the model of the complex object.

As methods for conveying building designs advance from sketches to descriptive geometry, and from computer-aided drafting and design (CAD) to building information modelling (BIM), the problem of interoperability between heterogeneous design systems arises. Due to disparate underlying schemas and inconsistent vocabularies, models from one application cannot be processed by another one without explicit mapping mechanisms.

In recent decades, the building industry has gradually shifted to the use of a standard, vendor-neutral data schema—the Industry Foundation Classes (IFC)—to represent building models in addressing the interoperability problem during design exchange scenarios. Based on this concept, software vendors implement their own proprietary export and import routines to release and consume the information in accordance with the specified standard.

However, the IFC-centric design collaboration is suboptimal because it is file-based, its semantics are often incomplete, giving a very poor understanding of interrelation between sub-models of different disciplines (or not giving it at all), and it does not incorporate or facilitate an incorporation of intelligent techniques for inter-object behavior analysis. The file-based nature of the design and information workflow for sharing models across disciplines is cumbersome, especially when multiple design alternatives and different versions are involved. Packaging of information and exchange in files does not assist in bridging gaps between discipline silos, and is not appropriate in scenarios in which information is dynamically changing. People working on the same construction project using different software applications need to complete fragmented tasks sequentially, although it is evident that the process would be far more efficient if they were carried out simultaneously. The semantics of objects are not consistent, and objects lose their classification identity through the exchanges, which renders them meaningless to the receiving applications. Finally, all the expression of design intent behavior that is modelled within the individual design BIM tools is lost when information is exported to neutral carrier, such as IFC files.

The term “design intent” refers to implicit meaningful semantics of inter-element relationships within a single sub-model, as well as between different elements of separate sub-models. Design intent is often conditioned by certain geometric and functional limitations of structural elements within a modeled object. In order to maintain the design intent in practice, it is essential to maintain implicit geometric and functional relationships when making changes to a model or sub-model.

As known in the art, in order to address issues introduced by the unregulated sharing of information, software vendors have developed cloud-based solutions to host BIM models, their sub-models and other building related documents in centralized data repositories—also known as common data environments (CDE)—to ensure that all authorized project participants can uniformly access and share the most up-to-date information according to predefined standards. Ownerships, edit records, and historical versions of files are automatically logged in the CDEs for the full traceability of every piece of information entered. Some of the most advanced systems allow users to work simultaneously on the same files through object-locking mechanisms, although they are restricted to a single vendor ecosystem and a single disciplinary design. Hence, by using the above-described tools, the users become able to work simultaneously on designing a single sub-model, but still have no efficient tool to develop separate sub-models covering different aspects and disciplines in a collaborative manner.

Although the emergence of commercial cloud-based CDEs to some degree mitigates the complex, disordered, and inefficient characteristics inherent to the conventional file-based exchange of substantial building information, coordinating designs and resolving conflicts remain largely manual processes, making human intervention indispensable for maintaining consistency between federated building models. Since CDEs are merely file-based data management systems, the resolution of coordination is confined to the file level, providing only auxiliary design collaboration functions such as file-level version control and solid geometry-based clash detection. None of the current CDE systems is capable of or intelligent enough to provide users with proactive, structural-element-level design support that can automate design collaboration processes.

As is evident to a person skilled in the art, objects constituting the federated building models are implicitly related to one other in many ways-yet the models are stored independently as siloed files in CDEs without any meaningful connections between them. Such latent, meaningful semantics expressing the design intents between building objects across domains provide the basis for intelligent applications, since they dictate how objects in one discipline should behave in response to changes made to objects in another related discipline. The lack of such object-level semantic relationships may be considered a decisive factor in the absence of proactive design coordination solutions from the market.

### SUMMARY OF THE INVENTION

Accordingly, there is a need for a system and method of federated computer-aided modeling which would provide an improvement of the respective technological field by mitigating the abovementioned interoperability problem, improving collaboration efficiency, increasing compatibility and consistency across discipline-specific sub-models, thereby reducing federated modeling processes duration, in particular, by reducing the number of redundant manual and semi-manual operations required to bring into line sub-models created by technical specialists of different disciplines. More specifically, there is a need for federated computer-aided modelling techniques, which would provide an explicit machine-understandable description of inter-model (or inter-sub-model) relationships, thereby enabling intelligent functions that would facilitate the modelling process.

In the general aspect, the invention may be directed to a method of federated computer-aided modeling of an object, by at least one processor, the method including: obtaining a plurality of sub-models, complementary representing the object, wherein each sub-model consists of one or more structural elements defined by parameters thereof; for each sub-model, generating a sub-graph representation, having said structural elements and parameters thereof represented as semantic triples; analyzing said semantic triples taken from different sub-graph representations to detect interrelations therebetween; instantiating semantic connections between the generated sub-graph representations, based on detected interrelations, thereby obtaining a meta-graph representation of a model of the object; and developing the model of the object, based on the obtained meta-graph representation.

In another general aspect, the inventions may be directed to a system for federated computer-aided modeling of an object, the system including: a non-transitory memory device, wherein modules of instruction code are stored, and at least one processor associated with the memory device, and configured to execute the modules of instruction code, whereupon execution of said modules of instruction code, the at least one processor is configured to: obtain a plurality of sub-models, complementary representing the object, wherein each sub-model consists of one or more structural elements defined by parameters thereof; for each sub-model, generate a sub-graph representation, having said structural elements and parameters thereof represented as semantic triples; analyze said semantic triples taken from different sub-graph representations to detect interrelations therebetween; instantiate semantic connections between the generated sub-graph representations, based on detected interrelations, thereby obtaining a meta-graph representation of a federated model of the object; and develop the model of the object, based on the obtained meta-graph representation.

In some embodiments, said sub-models of the plurality of sub-models may represent different design domains.

In some embodiments, said federated computer-aided modeling may pertain to Building information modeling (BIM) and the object may be a built object.

In some embodiments, at least one of said semantic triples may include elements selected from the list consisting of: (i) at least one node data element corresponding to said one or more structural elements or semantic relationships therebetween, (ii) at least one edge data element corresponding to semantic relationships between said node data elements, and (iii) at least one attribute data element representing an attribute associated with said at least one node data element or at least one edge data element.

In some embodiments, said semantic relationships may represent at least one of (i) spatial relationships; and (ii) functional relationships.

In some embodiments, said spatial relationships may include at least one of (i) topological relationships; (ii) distance relationships; and (iii) directional relationships.

In some embodiments, said parameters may be selected from the list consisting of (i) parameters defining geometrical characteristics of a respective structural element; (ii) parameters defining a position of the respective structural element within a respective sub-model; (iii) parameters defining an orientation of the respective structural element within the respective sub-model; (iv) parameters defining a material type of the respective structural element; (v) parameters defining a color of the respective structural element; (vi) parameters defining a functional characteristic of the respective structural element; and (vii) parameters defining a pattern of the respective structural element.

In some embodiments, instantiating semantic connections between the generated sub-graph representations may include: for at least one pair of node data elements corresponding to the structural elements and taken from different sub-graph representations, instantiating: (i) at least one node data element corresponding to semantic relationships between said at least one pair of node data elements; and (ii) a pair of edge data elements each connecting a respective node data element of the pair of node data elements with said at least one node data element corresponding to semantic relationships therebetween, and indicating whether the respective node data element of the pair of node data elements forms an object-predicate or a subject-predicate type of relationships with said at least one node data element corresponding to semantic relationships.

In some embodiments, said at least one node data element corresponding to semantic relationships may include: (i) at least one node data element representing a current condition of said semantic relationships between the pair of node data elements corresponding to the structural elements; and (ii) at least one node data element representing a constraint condition for semantic relationships between the pair of node data elements corresponding to the structural elements.

In some embodiments, a first sub-model of the plurality of sub-models may include a first structural element of the one or more structural elements, the first structural element corresponding to a first node data element of the pair of node data elements; a second sub-model of the plurality of sub-models may include a second structural element of the one or more structural elements, the second structural element corresponding to a second node data element of the pair of node data elements. Developing the model of the object may include: applying an alteration to at least one parameter of the first structural element; modifying the first node data element corresponding to said alteration; modifying the at least one node data element representing the current condition of said semantic relationships between the pair of node data elements, according to the modified first node data element; determining an incompliance of said current condition with said constraint condition; and further developing the model, based on the incompliance.

In some embodiments, developing the model, based on the incompliance, may include providing a message indicating the incompliance via a user interface (UI) of a respective computer-aided modelling tool for developing at least one of the first sub-model and the second sub-model.

In some embodiments, further developing the model, based on the incompliance, may include providing a respective alteration to at least one parameter of the second structural element to fix the incompliance, or providing a respective alteration to at least one parameter of the first structural element to fix the incompliance.

In some embodiments, at least one node data element representing the current condition may be associated with at least one attribute data element representing an attribute selected from the list consisting of: (i) a topology type enumerated value; (ii) an offset value indicating distance between respective structural elements; and (iii) a binary value indicating presence of a contact between the respective structural elements.

In some embodiments, said at least one node data element representing the constraint condition may be associated with at least one attribute data element representing an attribute selected from the list consisting of: (i) a physical connection type enumerated value taken from a list of predefined physical connection types; (ii) a constraint direction indication value indicating direction in space in which the constraint condition is applied; and (iii) a constraint threshold value defining the constraint condition; (iv) a comparison operator associated with the constraint threshold value and further defining the constraint condition; and (v) a constraint status value indicating whether the constraint condition is fulfilled or violated.

In some embodiments, instantiating semantic connections between the generated sub-graph representations may further include inferring a respectively pretrained machine-learning (ML)-based model on the generated sub-graph representations to instantiate semantic connections therebetween.

In some embodiments, the method may further include receiving a plurality of training samples, each comprising a training plurality of sub-graph representations, associated with a respective training meta-graph representation connecting said training plurality of sub-graph representations; and applying the plurality of training samples to train the ML-based model to calculate a target meta-graph representation based on a target plurality of sub-graph representations.

In some embodiments, each of training meta-graph representations may include a training node data element representing an example of a current condition of semantic relationships between specific node data elements corresponding to the structural elements taken from different sub-graph representations of the training plurality of sub-graph representations. Training the ML-based model may include training the ML-based model to instantiate a target node data element representing a target constraint condition for semantic relationships between specific node data elements corresponding to the structural elements.

In some embodiments, each of said structural elements may be associated with a specific structural element type; and instantiating the at least one node data element representing the constraint condition may be further performed by selecting a predefined constraint condition for a respective pair of the specific structural element types.

In some embodiments, a first sub-model of the plurality of sub-models may include a first structural element, the first structural element corresponding to a first node data element of the pair of node data elements, the first node data element being in an original version; a second sub-model of the plurality of sub-models may include a second structural element, the second structural element corresponding to a second node data element of the pair of node data elements; and wherein developing the model of the object may include: applying an alteration to at least one parameter of the first structural element; instantiating an alternative version of the first node data element, according to said alteration; instantiating an alternative version of a node data element representing the current condition of semantic relationships between the pair of node data elements, based on the alternative version of the first node data element; providing a selection between said original and alternative versions via a user interface (UI) of a respective computer-aided modelling tool of the second sub-model.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a block diagram, depicting a computing device which may be included in a system for federated computer-aided modeling, according to some embodiments;

FIG. 2 is a block diagram, depicting a system for federated computer-aided modeling, according to some embodiments;

FIG. 3 is a block diagram, depicting a general structure of a meta-graph representation generated by the system for federated computer-aided modeling, according to some embodiments;

FIG. 4 is an example of a meta-graph representation generated by the system for federated computer-aided modeling, according to some embodiments; and

FIG. 5 is a flow diagram, depicting a method of federated computer-aided modeling, according to some embodiments.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention. Some features or elements described with respect to one embodiment may be combined with features or elements described with respect to other embodiments. For the sake of clarity, discussion of same or similar features or elements may not be repeated.

Although embodiments of the invention are not limited in this regard, discussions utilizing terms such as, for example, “processing,” “computing,” “calculating,” “determining,” “establishing”, “analyzing”, “checking”, “choosing”, “selecting”, “omitting”, “training” or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium that may store instructions to perform operations and/or processes.

Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term “set” when used herein may include one or more items.

It shall be understood that, in the context of the present description, the term “object” may refer to the object of federated modeling as a whole, e.g., a built object, such as a building, bridge, dam, stadium, railway etc. Accordingly, the term “model” may refer to entire computer-aided model of “the object”. In turn, the term “sub-model” may refer to a computer-aided model providing partial representation of “the object”, e.g., representing an architectural or structural aspects of it, or representing its subsystems or sub-elements separately, e.g., representing Mechanical, Electrical, and Plumbing (MEP) systems. Complete plurality of “sub-models” complementary represent “the object” as a whole, thereby forming “the model” of “the object” of federated computer-aided modeling.

The term “structural element” may be used herein as a reference to elements forming the structure of a respective model or sub-model, e.g., to a sub-model element that represents a specific wall, column, pipe etc. of a federated modeling object. Hence, the term “structural element” may not necessarily refer to an element of a model or sub-model pertaining to structural engineering. E.g., “structural element” may represent an element of an architectural sub-model or MEP sub-model.

It shall be understood that terms “semantics”, “semantic triples”, “nodes” (or “node data elements”), “edges” (or “edge data elements”), “relationships”, “subject-predicate relationships”, “object-predicate relationships” or the like refer herein to the known-in-the-art concept of graph databases and graph structures of data representation (such as Resource Description Frameworks (RDF)). The meaning of the abovementioned terms may be easily recognized by the person ordinarily skilled in the art. These terms shall not be confused with similar ones referring to any non-technical aspects irrelevant to the present invention and to technology related thereto.

Unless explicitly stated, the method embodiments described herein are not constrained to particular order or sequence. Additionally, some of the described method embodiments or elements thereof can occur or be performed simultaneously, at the same point in time, concurrently, or iteratively and repeatedly.

In embodiments of the present invention, some steps of the claimed method may be performed using machine-learning (ML)-based models. ML-based models may be configured or “trained” for a specific task, e.g., classification or regression.

In some embodiments, ML-based models may be artificial neural networks (ANN).

A neural network (NN) or an artificial neural network (ANN), e.g., a neural network implementing a machine learning (ML) or artificial intelligence (AI) function, may refer to an information processing paradigm that may include nodes, referred to as neurons, organized into layers, with links between the neurons. The links may transfer signals between neurons and may be associated with weights. A NN may be configured or trained for a specific task, e.g., pattern recognition or classification. Training a NN for the specific task may involve adjusting these weights based on examples. Each neuron of an intermediate or last layer may receive an input signal, e.g., a weighted sum of output signals from other neurons, and may process the input signal using a linear or nonlinear function (e.g., an activation function). The results of the input and intermediate layers may be transferred to other neurons and the results of the output layer may be provided as the output of the NN. Typically, the neurons and links within a NN are represented by mathematical constructs, such as activation functions and matrices of data elements and weights. A processor, e.g., CPUs or graphics processing units (GPUs), or a dedicated hardware device may perform the relevant calculations.

It should be obvious for the one ordinarily skilled in the art that various ML-based models can be implemented without departing from the essence of the present invention. It should also be understood, that in some embodiments ML-based model may be a single ML-based model or a set (ensemble) of ML-based models realizing as a whole the same function as a single one. Hence, in view of the scope of the present invention, the abovementioned variants should be considered equivalent.

As can be seen, the present invention provides the following solution to the indicated drawbacks of the prior art.

First, it is suggested to generate, for each sub-model, a sub-graph representation, consisting of semantic triples, thereby converting each sub-model data to the uniform format. E.g., such sub-graph representation may contain semantic triples representing structural elements, spatial (e.g., topological, directional, distance-related) and functional relationships therebetween, their geometric characteristics, either simplified or full etc.

Then, it is suggested to detect interrelations between semantic triples of different sub-graph representations, e.g., interrelations between nodes representing structural elements of different sub-models. Such interrelations may be based on similarities of said spatial and functional characteristics. E.g., two structural elements of different sub-models may intersect, be parallel or perpendicular to each other, be located at the same place and have similar geometrical characteristics, meaning that they represent the same element of the object, e.g., same wall in different sub-models: structural and architectural, etc.

Then it is suggested to instantiate semantic connections between sub-graph representations, based on the identified interrelations. At this stage, a meta-graph representation is formed, providing information on how the sub-models are related to each other. The important aspect of such meta-graph representation is that it does not need to contain exact geometrical data about each structural element separately, but rather the detailed information on how the structural elements interrelate between sub-graph representations (and between sub-models, accordingly), thereby accentuating semantically meaningful aspects that may pertain to what is commonly known as “design intent”. In practice, design intent aspects may be represented explicitly by defining desired or required state (constraint conditions, e.g., certain acceptable ranges of distances between structural elements, acceptable topological values etc.), to which structural elements, or interrelations therebetween, may or may not conform.

Finally, the model may be further developed using said meta-graph representation. Such a federated modelling may further include: instantly updating meta-graph representation, checking correspondence of current and constraint conditions (further described in details), propagating changes between sub-models and evaluating their consistency, analyzing a plurality of meta-graph representations of different federated models to apply artificial intelligence (AI) and machine learning (ML) techniques in order to define design-intent constraint conditions limiting relationships between structural elements of different sub-models etc. The federated modeling may even include functions of providing design suggestions using AI and ML techniques (e.g., according to specific predefined pattern, e.g., specific type of room (living room, bathroom etc.), specific type of building (theater, warehouse etc.)). Said accentuation on relationships between structural elements makes the suggested meta-graph representation data a suitable input for an efficient application of various computational methods (either statistical or deterministic, ML-based or rule-based), if compared to the hypothetical redundant and irrelevant input formed based on the exact geometrical characteristics initially used to define each sub-model separately. Hence, the claimed invention provides a reliable federated modeling tool that enables computer-aided design intent investigation and appliance.

It shall be understood that although the present description mostly refers to BIM, built objects, structural elements, like walls and pipes, spatial relationships between structural elements etc., all such specific aspects are provided for the purpose of clarity and represent a non-exclusive example illustrating the concept of the present invention. The present invention may be related to any possible type of computer-aided modelling, operating with different types of objects, structural elements, and other categories of relationships between structural elements.

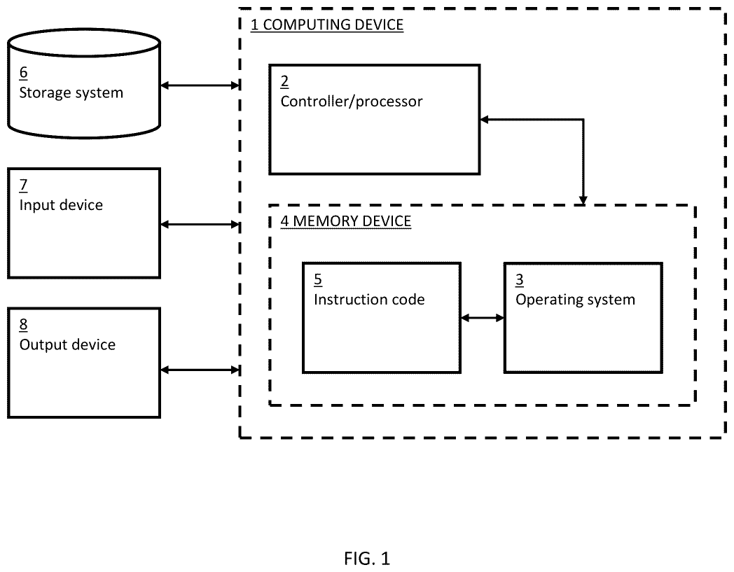

Reference is now made to FIG. 1, which is a block diagram depicting a computing device, which may be included within an embodiment of the system for federated computer-aided modeling, according to some embodiments.

Computing device 1 may include a processor or controller 2 that may be, for example, a central processing unit (CPU) processor, a chip or any suitable computing or computational device, an operating system 3, a memory device 4, instruction code 5, a storage system 6, input devices 7 and output devices 8. Processor 2 (or one or more controllers or processors, possibly across multiple units or devices) may be configured to carry out methods described herein, and/or to execute or act as the various modules, units, etc. More than one computing device 1 may be included in, and one or more computing devices 1 may act as the components of, a system according to embodiments of the invention.

Operating system 3 may be or may include any code segment (e.g., one similar to instruction code 5 described herein) designed and/or configured to perform tasks involving coordination, scheduling, arbitration, supervising, controlling or otherwise managing operation of computing device 1, for example, scheduling execution of software programs or tasks or enabling software programs or other modules or units to communicate. Operating system 3 may be a commercial operating system. It will be noted that an operating system 3 may be an optional component, e.g., in some embodiments, a system may include a computing device that does not require or include an operating system 3.

Memory device 4 may be or may include, for example, a Random-Access Memory (RAM), a read only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short-term memory unit, a long-term memory unit, or other suitable memory units or storage units. Memory device 4 may be or may include a plurality of possibly different memory units. Memory device 4 may be a computer or processor non-transitory readable medium, or a computer non-transitory storage medium, e.g., a RAM. In one embodiment, a non-transitory storage medium such as memory device 4, a hard disk drive, another storage device, etc. may store instructions or code which when executed by a processor may cause the processor to carry out methods as described herein.

Instruction code 5 may be any executable code, e.g., an application, a program, a process, task, or script. Instruction code 5 may be executed by processor or controller 2 possibly under control of operating system 3. For example, instruction code 5 may be a standalone application or an API module that may be configured to perform steps of the claimed method, e.g., to generate sub-graph representations, analyze semantic triples to detect interrelations therebetween, instantiate semantic connections between sub-graph representations etc., as further described herein. Although, for the sake of clarity, a single item of instruction code 5 is shown in FIG. 1, a system according to some embodiments of the invention may include a plurality of executable code segments or modules similar to instruction code 5 that may be loaded into memory device 4 and cause processor 2 to carry out methods described herein.

Storage system 6 may be or may include, for example, a flash memory as known in the art, a memory that is internal to, or embedded in, a micro controller or chip as known in the art, a hard disk drive, a CD-Recordable (CD-R) drive, a Blu-ray disk (BD), a universal serial bus (USB) device or other suitable removable and/or fixed storage unit. Various types of input and output data may be stored in storage system 6 and may be loaded from storage system 6 into memory device 4 where it may be processed by processor or controller 2. In some embodiments, some of the components shown in FIG. 1 may be omitted. For example, memory device 4 may be a non-volatile memory having the storage capacity of storage system 6. Accordingly, although shown as a separate component, storage system 6 may be embedded or included in memory device 4.

Input devices 7 may be or may include any suitable input devices, components, or systems, e.g., a detachable keyboard or keypad, a mouse and the like. Output devices 8 may include one or more (possibly detachable) displays or monitors, speakers and/or any other suitable output devices. Any applicable input/output (I/O) devices may be connected to Computing device 1 as shown by blocks 7 and 8. For example, a wired or wireless network interface card (NIC), a universal serial bus (USB) device or external hard drive may be included in input devices 7 and/or output devices 8. It will be recognized that any suitable number of input devices 7 and output devices 8 may be operatively connected to Computing device 1 as shown by blocks 7 and 8.

A system according to some embodiments of the invention may include components such as, but not limited to, a plurality of central processing units (CPU) or any other suitable multi-purpose or specific processors or controllers (e.g., similar to element 2), a plurality of input units, a plurality of output units, a plurality of memory units, and a plurality of storage units.

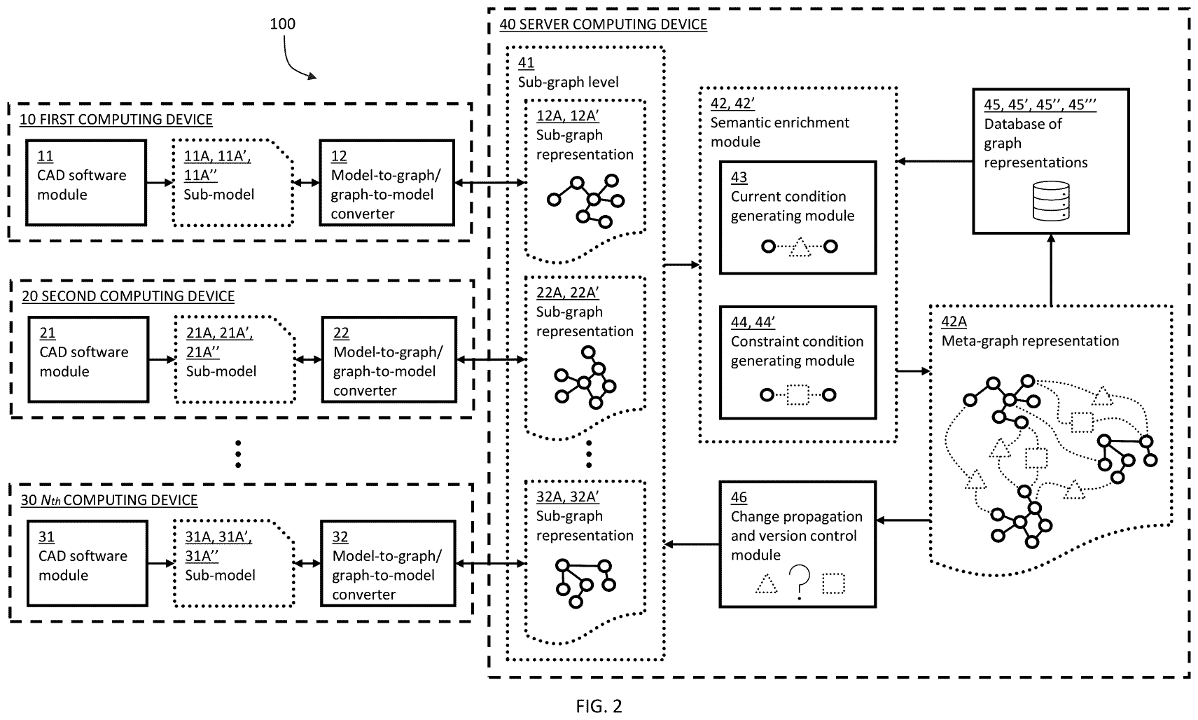

Reference is now made to FIG. 2 depicting system 100 for federated computer-aided modeling, according to some embodiments.

According to some embodiments of the invention, system 100 may be implemented as a software module, a hardware module, or any combination thereof. For example, system 100 may be or may include a computing device such as element 1 of FIG. 1. Furthermore, system 100 may be adapted to execute one or more modules of instruction code (e.g., element 5 of FIG. 1) to request, receive, analyze, calculate and produce various data. In particular, and as further described in detail herein, system 100 may be adapted to execute one or more modules of instruction code (e.g., element 5 of FIG. 1) in order to perform steps of the claimed method.

As shown in FIG. 2, arrows may represent flow of one or more data elements to and from system 100 and/or among modules or elements of system 100. Some arrows have been omitted in FIG. 2 for the purpose of clarity.

In some embodiments, system 100 may include a plurality of computing devices, e.g., first computing device 10, second computing device 20 and nih computing device 30. In some embodiments, system 100 may further include server computing device 40. In some embodiments said computing devices 10, 20 and 30 may be connected to server computing device via network interface. In some embodiments, server computing device 40 may represent a cloud server, and the connection may be established via internet communication protocols. It shall be understood that a division between computing devices 10, 20, 30 and 40 may be physical, virtual, or combined.

In some embodiments, each of computing devices 10, 20 and 30 may include CAD software modules 11, 21 and 31, respectively. CAD software modules 11, 21 and 31 may be configured to carry out common modelling and designing procedures, required to construct sub-models 11A, 21A, and 31A accordingly, e.g., by receiving commands from a respective user via user interface (UI) tools. For example, CAD software modules 11, 21, and 31 may be such known CAD designing software as AutoCAD, Autodesk Inventor, SolidWorks or the like.

It should be understood that, according to the concept of the present invention, CAD software modules 11, 21 and 31 may represent different design domains and completely irrelated stand-alone software solutions, as one of the most important aspects of the present invention lies in providing a universal approach for determining design-intent aspects, which unite plurality of sub-models (e.g., sub-models 11A, 21A and 31A), wherein the approach is not limited to the usage of specific CAD software or to the usage of the same CAD software amongst computing devices 10, 20 and 30.

In some embodiments, each of the obtained sub-models 11A, 21A and 31A may consist of a plurality of structural elements 11A′, 21A′, and 31A′, respectively, defined by parameters 11A″, 21A″, and 31A″ thereof. E.g., such structural elements 11A′, 21A′, and 31A′ may correspond to specific wall of a building, specific pipe segment of a water supply system etc. In some embodiments, said parameters 11A″, 21A″, and 31A″ may represent (i) parameters defining geometrical characteristics of a respective structural element; (ii) parameters defining a position of the respective structural element within a respective sub-model; (iii) parameters defining an orientation of the respective structural element within the respective sub-model; (iv) parameters defining a material type of the respective structural element; (v) parameters defining a color of the respective structural element; (vi) parameters defining a functional characteristic of the respective structural element (e.g., function of connecting two other structural elements, function of supporting another structural element etc.); and (vii) parameters defining a pattern of the respective structural element.

It shall be understood that the abovementioned parameters do not form a complete list, but rather a non-exclusive illustrative example of the parameters 11A″, 21A″, and 31A″ that may be used to characterize structural elements 11A′, 21A′, and 31A′.

In some embodiments, the complete plurality of sub-models (e.g., including sub-models 11A, 21A and 31A) may complementarily represent the respective object of federated modelling (e.g., a building, a bridge etc.), that is wherein each of sub-models has its own aspects of the object modelled, which, if considered together with the aspects represented by rest sub-models, from the desired complete model of the object (or its part).

In some embodiments, computing devices 10, 20 and 30 may include model-to-graph/graph-to-model converters 12, 22, and 32, respectively. Converters 12, 22, and 32 may be configured to generate, for respective model, sub-graph representations 12A, 22A and 32A, respectively. Converters 12, 22 and 32 may be further configured to generate sub-graph representations 12A, 22A and 32A, by making respective structural elements 11A′, 21A′, and 31A′ and parameters 11A″, 21A″, and 31A″ thereof represented as semantic triples 12A′, 22A′ and 32A′.

In some embodiments, said semantic triples 12A′, 22A′ and 32A′ may include the following elements: (i) node data elements (marked with circles) corresponding to said structural elements (e.g., structural elements 11A′, 21A′, and 31A′) or semantic relationships therebetween, (ii) at least one edge data element (marked with lines connecting circles-nodes) corresponding to semantic relationships between said node data elements, and (iii) at least one attribute data element representing an attribute associated with said at least one node data element or at least one edge data element.

For example, one of the node data elements may represent a structural element “wall”, characterized by attribute data elements defining its size, shape and position; another node data element may represent a structural element “window”, characterized by attribute data elements defining its size, shape and position; while edge data element, connecting said node data elements may represent semantic relationships between respective node data elements, e.g., indicate that the window is located in the wall and forms a respective opening in the wall.

In some embodiments, said semantic relationships may represent spatial relationships—e.g., the ones that relate to interposition of elements—, or functional relationships—the ones that indicate function of one element with respect to another, e.g., supporting function, connecting function etc. In particular, in some embodiments, spatial relationships may represent (i) topological relationships; (ii) distance relationships; and (iii) directional relationships.

In some embodiments, generated sub-graph representations 12A, 22A and 32A (sub-graph level 41) may be instantly uploaded to server computing device 40 for further processing.

In some embodiments, server computing device 40 may further include semantic enrichment module 42. Semantic enrichment module 42 may be further configured to analyze said semantic triples 12A′, 22A′ and 32A′ taken from different sub-graph representations (e.g., representations 12A, 22A and 32A), to detect interrelations therebetween.

In some embodiments, semantic enrichment module 42 may be further configured to instantiate semantic connections between generated sub-graph representations 12A, 22A and 32A, based on detected interrelations, thereby obtaining meta-graph representation 42A of the model of the object.

In some embodiments, said instantiation of semantic connections may include instantiation of new node data elements and edge data elements connecting node data elements taken from different sub-graph representations 12A, 22A and 32A.

In particular, in some embodiments, semantic enrichment module 42 may be further configured to instantiate semantic connections between sub-graph representations 12A, 22A and 32A in the following way. For a pair of node data elements corresponding to structural elements 11A′, 21A′, and 31A′ and taken from different sub-graph representations 12A, 22A and 32A, semantic enrichment module 42 may be further configured to instantiate: (i) at least one node data element (marked with triangles and squares) corresponding to semantic relationships between said pair of node data elements; and (ii) a pair of edge data elements (marked with lines connecting respective triangles and squares with circles-nodes of sub-graph representations) each connecting a respective node data element of the pair of node data elements with said at least one node data element corresponding to semantic relationships therebetween. Said pair of edge data elements may indicate whether the respective node data element of the pair of node data elements forms an object-predicate or a subject-predicate type of relationships with said at least one node data element corresponding to semantic relationships.

For example, semantic enrichment module 42 may be further configured to perform said interrelation detection and semantic connection instantiation in the following way. For this method, each structural element of respective sub-model 11A, 21A, and 31A may be represented in the respective sub-graph representation 12A, 22A and 32A using simplified geometry, e.g., may be substituted by a minimal bounding box, required to cover respective element, and characterized by its orientation and size.

In the first step, module 42 may traverse all possible pairs of nodes, representing structural elements 11A′, 21A′, and 31A′ from different sub-graph representations 12A, 22A and 32A. and compare the bounding box geometries and orientations. If they overlap one another in any of the three axis directions, a respective node data element of meta-graph representation 42A (the one corresponding to semantic relationships between the pair of nodes of sub-graph representations 12A, 22A and 32A) is instantiated and connected to the respective node data elements of sub-graph representations 12A, 22A and 32A via abovementioned pair of edge data elements (the ones indicating object-predicate and subject-predicate relationships). Module 42 may be further configured to apply a Boolean solid intersection test using either abovementioned simplified geometry or exact geometry (for more precise calculations), to determine if respective structural elements 11A′, 21A′, and 31A′ are in contact or overlap, and to indicate the result as a respective attribute data element value of the corresponding node data element of meta-graph representation 42A. In the next step, module 42 may be further configured to traverse the semantically related pairs of node data elements of sub-graph representations 12A, 22A and 32A and tests them for two conditions: (i) presence of contact or overlap with a pre-set tolerance, and membership of a predefined set of logically possible domain-type correspondence type pairs (such as Architectural-Floor-Structural-Slab; Architectural-Toilet-Plumbing-Toilet etc.). Module 42 may be further configured to instantiate the attribute data elements of the respective node data element of meta-graph representation 42A if the abovementioned conditions are satisfied.

In some embodiments, according to the concept of the present invention, semantic connections of meta-graph representation 42A may be divided into two main groups: the ones representing current conditions of semantic relationships between the pair of node data elements corresponding to structural elements 11A′, 21A′, and 31A′ of different sub-graph representations 12A, 22A and 32A; and the ones representing constraint conditions of the same. Current conditions may be evaluated by analyzing sub-graph representations (e.g., representations 12A, 22A and 32A) pertaining to the target model, whilst constraint conditions require an additional input, as further discussed in detail herein.

Accordingly, in some embodiments, enrichment module 42 may include current condition generating module 43. Current condition generating module 43 may be configured to instantiate node data elements representing abovementioned current conditions (marked with triangles) of said semantic relationships between the pair of node data elements corresponding to structural elements 11A′, 21A′, and 31A′. In some embodiments, enrichment module 42 may further include constraint condition generating module 44. Constraint condition generating module 44 may be configured to instantiate node data elements representing abovementioned constraint conditions (marked with squares) for semantic relationships between the pair of node data elements corresponding to structural elements 11A′, 21A′, and 31A′.

As indicated above, one of the important aspects of the present invention lies in that the sub-graph and meta graph representations 12A, 22A, 32A and 42A represent relationships between structural elements 11A′, 21A′, and 31A′ in the format that enables usage of various computational methods (e.g., ML-based or rule-based) to derive higher level knowledge, e.g., knowledge about the implied design intent.

For example, in order to derive design-intent knowledge the following may be carried out, according to some embodiments.

In some embodiments, server computing device 40 may further include database 45 of graph representations. In some embodiments, server computing device 40 may be further configured to receive a plurality of training samples 45′, each comprising a training plurality of sub-graph representations 45″, associated with a respective training meta-graph representation 45′″ connecting said training plurality of sub-graph representations 45″; and store these training samples 45′ in database 45. Said sub-graph and respective meta-graph representations 45″ and 45′″ may be obtained by instantiating semantic connections representing current condition (as described above) manually or using rule-based computational methods. Said sub-graph and respective meta-graph representations 45″ and 45′″ may be shared between similar systems and models, may be provided by third-party providers and/or accumulated by system 100 based on previously conducted federated modelling projects.

In some embodiments, semantic enrichment module 42 may further include ML-based training module 42′, and constraint condition generating module 44 may include ML-based model 44′.

ML-based training module 42′ may be configured to apply the plurality of training samples 45′ to train ML-based model 44′ to calculate a target meta-graph representation (e.g., meta-graph representation 42A) based on a target plurality of sub-graph representations (e.g., sub-graph representations 12A, 22A and 32A).

In particular, each of training meta-graph representations may include training node data elements, each representing an example of a current condition of semantic relationships between specific node data elements corresponding to the structural elements taken from different sub-graph representations of the training plurality of sub-graph representations 45″. Accordingly, ML-based training module 42′ may be further configured to perform said training of ML-based model 44′ to instantiate target node data elements representing target constraint conditions for semantic relationships between specific node data elements (e.g., node data elements of semantic triples 12A′, 22A′ and 32A′) corresponding to the structural elements (e.g., structural elements 11A′, 21A′, and 31A′).

For example, plurality of training samples 45′ may include (i) node data elements of different sub-graph representations 45″, indicating two related objects: a wall and a pipe of certain diameter attached thereto; and (ii) meta-graph representations 45′″ having node data elements corresponding to a respective plurality of current conditions of semantic relationships between the node data elements corresponding to the wall and the pipe. The plurality of current conditions may, e.g., be represented by respective attribute data elements representing topological relationships which indicate that the pipe in each case is positioned parallel to the wall and prolongs in the vertical direction. The plurality of current conditions may, e.g., be further represented by respective attribute data elements representing distance relationships, which may indicate explicit distance values between the wall and the pipe in each particular case (e.g., 21 mm, 24 mm, 29 mm, 30 mm etc.). After performing the abovementioned training, based on such examples of current conditions of semantic relationships, ML-based model 44′ may be able to (i) receive target node data elements of sub-graph representations (e.g., sub-graph representations 12A, 22A and 32A) representing structural elements of the same type (e.g., a wall and a pipe of certain diameter), and (ii) instantiate, for such node data elements of sub-graph representations (e.g., sub-graph representations 12A, 22A and 32A), node data elements representing target constraint conditions. According to the example, such constraint conditions may be represented by attribute data elements, indicating that topology relationships in such case are expected to be indicating that the pipe is positioned parallel to the wall and prolongs in the vertical direction and that distance relationships are expected to be indicating that the distance between the pipe and the wall must fall within 21-30 mm range.

It will be recognized by the person skilled in the art that, in order to perform said training, various conventional ML and AI techniques may be applied (such as Linear Regression, Logistic Regression, Random Forest, Backpropagation, Gradient Descent etc.), as well as various known architectures may be selected as a basis for ML-based model 44′. Accordingly, it should be understood that the present invention is not limited in this regard.

Accordingly, in the respective embodiments, constraint condition generating module 44 may be further configured to instantiate semantic connections between the generated sub-graph representations by inferring a respectively pretrained (e.g., as described above) machine-learning (ML)-based model (e.g., ML-based model 44′) on the generated sub-graph representations (e.g., sub-graph representations 12A, 22A and 32A) to instantiate semantic connections therebetween.

Hence, such constraint conditions, and respective node data elements that represent them, may explicitly provide the desired design-intent knowledge described above.

In some additional or alternative embodiments, design-intent knowledge may be derived in another way.

E.g., in some embodiments, converters 12, 22, and 32 may be further configured to associate each of said structural elements 11A′, 21A′, and 31A′ with specific predefined structural element types (e.g., sewage pipe, bearing wall etc.). Semantic enrichment module 42 may be further configured to store said specific predefined structural element types and predefined constraint condition node data elements, associated with a respective pair of the structural element types. Accordingly, constraint condition generating module 44 may be further configured to instantiate the node data elements representing constraint conditions by selecting a predefined constraint condition for a respective pair of the specific structural element types.

In some additional or alternative embodiments, yet another method of deriving design-intent knowledge may be applied. E.g., constraint condition generating module 44 may be further configured to instantiate constraint conditions for one type of attribute data elements based on current condition of another type of attribute data elements. E.g., if the diameter of the pipe is between 30-50 mm, the distance between the pipe and the wall is expected to be in the 5-15 mm range, etc.

It shall be understood that all abovementioned approaches of instantiating constraint conditions may be applied separately or in combination, depending on the desired embodiment.

In some embodiments, generated meta-graph representation 42A along with respective sub-graph representations 12A, 22A and 32A may be further recorded to database 45, and applied, by training module 42′, as training sample 45′ for further retraining ML-based model 44′.

Once the design-intent knowledge is obtained (the node data elements representing constraint conditions are instantiated), this knowledge may be applied to improve the modeling process.

Accordingly, in some embodiments, server computing device 40 may further include change propagation and version control module 46.

In some embodiments, first sub-model 11A may include a first structural element of structural elements 11A′, the first structural element corresponding to a first node data element of the pair of node data elements representing related structural elements 11A′, and 21A′ of respective sub-models 11A, and 21A. Second sub-model 21A may include a second structural element of structural elements 21A′, the second structural element corresponding to a second node data element of the pair of node data elements representing related structural elements 11A′, and 21A′ of respective sub-models 11A, and 21A. In some embodiments, the further developing of the model of the object (once the node data elements representing constraint conditions are instantiated) may further include (i) applying an alteration to at least one parameter 11A″ of first structural element 11A′, which may be performed by a user via UI of CAD software module 11. Accordingly, converter 12 may be further configured to modify the first node data element corresponding to said alteration. Accordingly, current condition generating module 43 may be further configured to modify the at least one node data element representing the current condition of said semantic relationships between the pair of node data elements, according to the modified first node data element.

Change propagation and version control module 46 may be further configured to determine an incompliance of said current condition with respective constraint condition, defined by node data element representing constraint conditions defined for the respective pair of node data elements representing pair of structural elements 11A′ and 21A′.

In some embodiments, change propagation and version control module 46 may be further configured to generate a message data element, indicating the determined incompliance, and transmit the message data element to either or both CAD software modules 11 and 21. Respective CAD software module 11 or 21 may be further configured to provide, based on the received message data element, a message indicating the incompliance, via a user interface (UI) of respective CAD software module 11 or 21. Thereby, each of the users may be instantly informed about the incompliance, and hence be able to make a respective alteration to at least one parameter 11A″ or 21A″ of first or second structural elements 11A′ and 21A′, respectively, to fix the incompliance.

As can be seen, such a change propagation and inter-sub-model consistency maintenance approach may provide a sound improvement of the technological field of computer-aided design and modeling, by facilitating federated modeling processes, reducing their duration, in particular, by reducing the number of redundant manual and semi-manual operations required to bring into line different sub-models (e.g., sub-models 11A and 21A).

In some additional or alternative embodiments, either or both converters 12 and 22 may be further configured to perform a respective alteration to at least one node, attribute, or edge data element, to fix the incompliance. Either or both converters 12 and 22 may be further configured to propagate the performed alteration to respective sub-model 11A or 21A, e.g., to perform a respective alteration to first or second structural elements 11A′ and 21A′, respectively, to fix the incompliance.

In some embodiments, change propagation and version control module 46 may be further configured to store multiple versions of semantic connections, according to performed alterations, and system 100 may be configured to provide the end user with the UI tools of selecting the desired version.

In particular, in some embodiments, first sub-model 11A may include first structural element 11A′, first structural element 11A′ corresponding to a first node data element of the pair of node data elements representing related structural elements 11A′, and 21A′ of respective sub-models 11A, and 21A. The first node data element may be considered as being represented in the original version. Accordingly, second sub-model 21A may include second structural element 21A′, second structural element 21A′ corresponding to a second node data element of the pair of node data elements representing related structural elements 11A′, and 21A′ of respective sub-models 11A, and 21A.

In some embodiments, the further developing of the model of the object (once the node data elements representing constraint conditions are instantiated) may include (i) applying an alteration to at least one parameter 11A″ of first structural element 11A′, which may be performed by a user via UI of CAD software module 11. Accordingly, converter 12 may be further configured to instantiate an alternative version of the first node data element, according to said alteration. Accordingly, current condition generating module 43 may be further configured to instantiate an alternative version of a node data element representing the current condition of semantic relationships between the pair of node data elements, based on the alternative version of the first node data element. Either or both CAD software modules 11 and 21 may be further configured to provide a selection between said original and alternative versions via UI. Converters 12 and 22, and current condition generating module 43 may be further configured to apply an alteration as described above, when receiving respective version selection from modules 11 or 21.

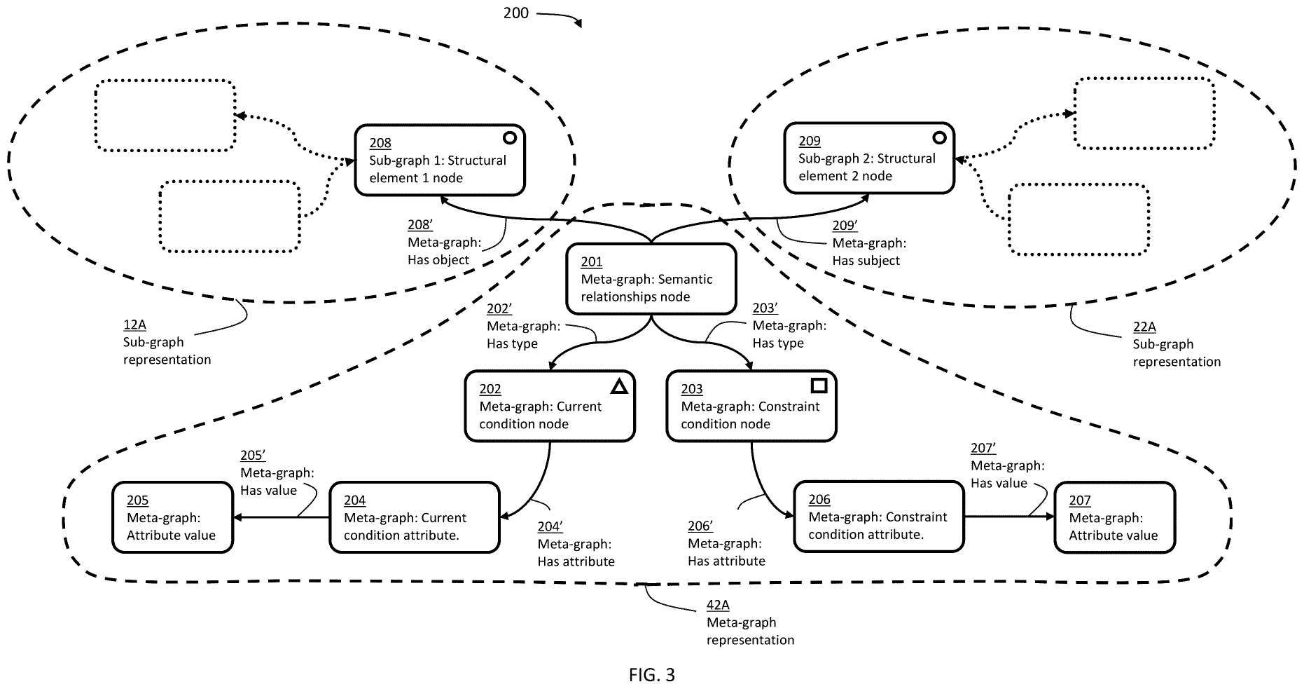

Reference is now made to FIG. 3 depicting a block diagram, representing a general structure of meta-graph representation 200 (e.g., such as meta-graph representation 42A) generated by system 100 for federated computer-aided modeling, according to some embodiments.

For the purpose of clarity, in the following description of graph representations terms “node data element”, “edge data element” and “attribute data element” may be substituted by “node”, “edge” and “attribute” respectively. These terms should be considered equivalent, as well as it shall be understood that these terms may equally refer to corresponding elements described with reference to FIG. 2. E.g., “semantic relationship node” may refer to “node data element corresponding to semantic relationships”, “current condition node” may refer to “node data element representing current condition of semantic relationships”, “structural element 1 node” may refer to “node data element corresponding to the structural element 11A′” etc.

As shown in FIG. 3, in result of instantiating semantic connections between sub-graph representations 12A and 22A (as shown in FIG. 2), semantic relationships node 201 of meta-graph representation 42A may be instantiated. Semantic relationships node 201 may, in turn, be connected to either or both current condition node 202 and constraint condition node 203 by respective edges 202′ and 203′, indicating “has type” semantic relationships therebetween. Same as in FIG. 2, current condition nodes are marked with triangles and constraint condition nodes are marked with squares.

Semantic relationships node 201 may be connected to structural element 1 node 208 of sub-graph representation 12A and structural element 2 node 209 of sub-graph representation 22A via a pair of edges 208′ and 209′, indicating “has object” and “has subject” (“object-predicate” and “subject-predicate”) semantic relationships, accordingly. Same as in FIG. 2, structural element nodes are marked with circles.

As shown in FIG. 3, sub-graph representations 12A and 22A may include other nodes and edges (e.g., corresponding to other structural elements 11A′ and 21A′, respectively), which may be connected to nodes 208 and 209 respectively.

In some embodiments, current condition node 202 may be connected to node representing attribute thereof-current condition attribute 204, via edge 204′ indicating “has attribute” semantic relationships between respective nodes. Current condition attribute 204 may be connected to node indicating attribute value 205, via edge 205′ indicating “has value” semantic relationships between respective nodes. It should be understood that current condition node 202 may be connected to multiple nodes representing attributes thereof, and that only one attribute 204 is shown herein for the purpose of clarity.

Accordingly, in some embodiments, constraint condition node 203 may be connected to node representing attribute thereof-constraint condition attribute 206, via edge 206′ indicating “has attribute” semantic relationships between respective nodes. Constraint condition attribute 206 may be connected to node indicating attribute value 207, via edge 207′ indicating “has value” semantic relationships between respective nodes. It should be understood that constraint condition node 203 may be connected to multiple nodes representing attributes thereof, and that only one attribute 204 is shown herein for the purpose of clarity.

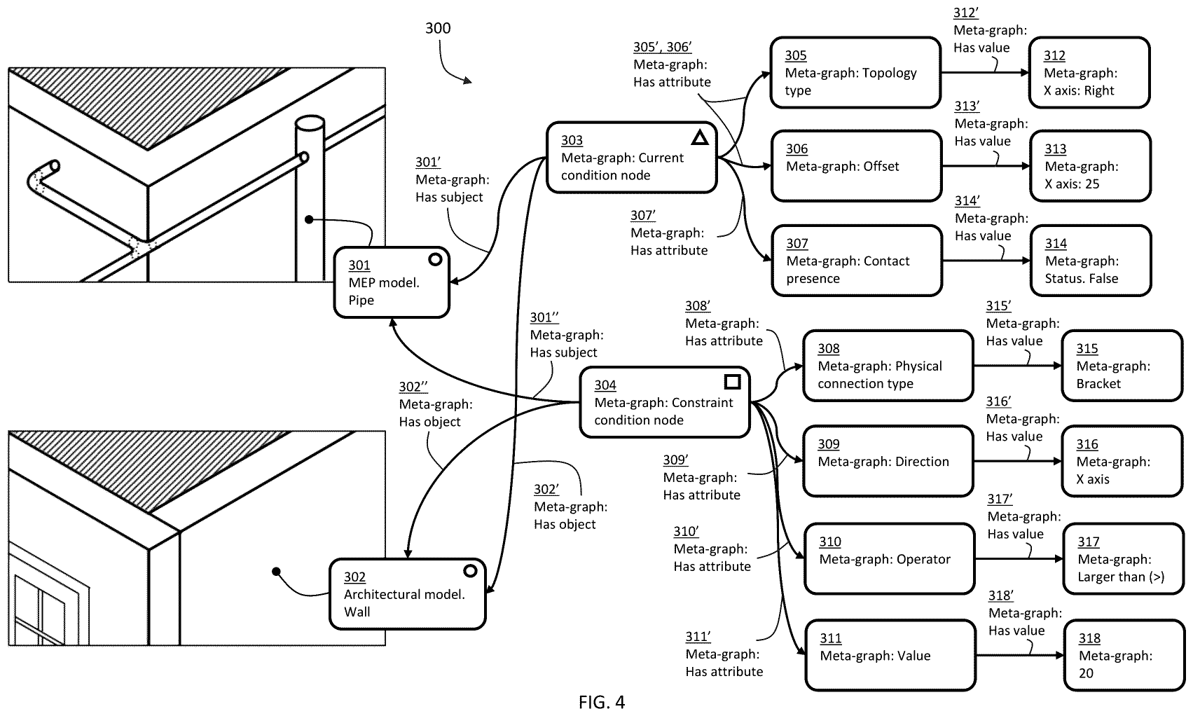

Reference is now made to FIG. 4 depicting an example of a meta-graph representation 300 generated by system 100 for federated computer-aided modeling, according to some embodiments.

The example represents an application of the concept of the present invention for federated modelling of BIM object-a building. As shown in FIG. 4, model of the building includes two sub-models: MEP model (shown in the upper left corner), designated for designing water supply system of the building, and architectural model (shown in the lower left corner), designated for designing architectural aspects of the building.

The MEP model may include structural element pipe 301, representing a respective segment of the water supply system. The architectural model may include structural element wall 302, representing respective wall of the building. If combine the indicated two sub-models, it may be understood from the obtained complete model that pipe 301 is supposed to be attached to wall 302, e.g., with brackets, and, consequently, shall be positioned parallel to wall 302 and at the certain distance suitable for such type of attachment.

Accordingly, as described with reference to FIG. 2, current condition node 303 may be instantiated, which may be connected to the following attributes: topology type 305, offset 306 and contact presence 307, via respective “has attribute” edges 305′, 306′ and 307′. Topology type 305 node may be further connected to value node 312 (via “has value” edge 312′), specifying the topology type—“X axis: Right”, meaning that currently pipe 301 is positioned on the right of wall 302 in X-axis direction. Offset 306 node may be further connected to value node 313 (via “has value” edge 313′), specifying the offset value—“X axis: 25 mm”, meaning, that distance between pipe 301 and wall 302 is 25 mm along the X-axis. Contact presence 307 node may be further connected to value node 314 (via “has value” edge 314′), specifying the contact presence value-“False”, meaning, that currently there is no contact between pipe 301 and wall 302.

Then, same as described with reference to FIG. 2, constraint condition code 304 may be instantiated, which may be connected to the following attributes: physical connection type 308, direction 309, operator 310 and constraint value 311, via respective “has attribute” edges 308′, 309′, 310′ and 311′. Physical connection type 308 node may be further connected to value node 315 (via “has value” edge 315′), specifying the physical connection type—“Bracket”, meaning that pipe 301 is designated (according to the implied design intent) to be connected to wall 302 via brackets. Direction 309 node may be further connected to value node 316 (via “has value” edge 316′), specifying the direction in which constraint may be applied—“X axis”, meaning that, according to the implied design intent, pipe 301 and wall 302 has certain constraint in their interposition in X-axis direction. Operator 310 node may be further connected to value node 317 (via “has value” edge 317′), specifying the operator for the constraint—“Larger than (>)”, meaning that, according to the implied design intent, pipe 301 and wall 302 has certain constraint in their interposition in X-axis direction, defined by this operator. Constraint value 311 node may be further connected to value node 318 (via “has value” edge 318′), specifying the value for the constraint—“20 mm”, meaning that, according to the implied design intent, pipe 301 and wall 302 has constraint in their interposition in X-axis direction, which is related to value 20 mm. In other words, constraint condition node 304 indicates that, according to the implied design intent, the distance between pipe 301 and wall 302 must be larger than 20 mm.

The following is an example of how the incompliance may be detected (according to aspects described with reference to FIG. 2).

E.g., the user developing said architectural model may perform an alteration-move said wall 30 mm further in X-axis direction. The converting module (such as converter 11, shown in FIG. 2) may be configured to propagate the alteration and modify respective node 302, in particular its attributes (not shown). Then, a current condition generating module (such as module 43 shown in FIG. 2) may modify current condition node 303. In particular, the current condition generating module may modify attributes 305, 306 and 307 accordingly—value node 312 will indicate topology type “contained in”, value node 313 will indicate offset “0 mm”, and value node 314 will indicate contact presence status “True”.

Then a change propagation and version control module (such as module 46 shown in FIG. 2) may compare the updated current conditions (attributes of node 303) with the above-described constrained conditions (attributes of node 304) and determine an incompliance therebetween—current offset 360 value 313 (“0”) is in conflict with the constraint that distance in direction 309 (“X axis”) between wall 302 and pipe 301 must be “larger than” (operator 310) “20 mm” (constraint value 311).

Accordingly, the proper actions may be further applied to inform users about the determined incompliance and to fix it, as described in detail with reference to FIG. 2.

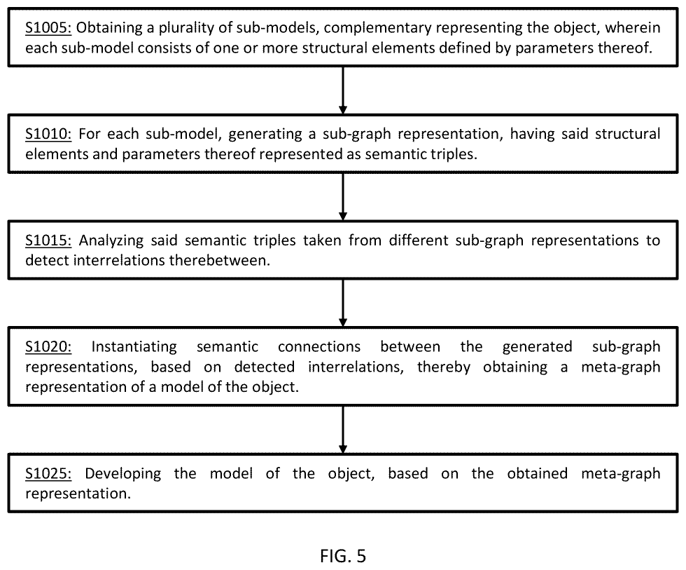

Referring now to FIG. 5, a flow diagram is presented, depicting a method of federated computer-aided modeling, by at least one processor, according to some embodiments.

As shown in step S1005, the at least one processor (e.g., processor 2 of FIG. 1) may obtain a plurality of sub-models (e.g., sub-models 11A, 21A, and 31A, as shown in FIG. 2), complementary representing the object, wherein each sub-model (e.g., sub-models 11A, 21A, and 31A, as shown in FIG. 2) consists of one or more structural elements (e.g., structural elements 11A′, 21A′, and 31A′, as shown in FIG. 2) defined by parameters thereof (e.g., parameters 11A″, 21A″, and 31A″, as shown in FIG. 2). Step S1005 may be carried out by CAD software modules 11, 21, and 31 (as described with reference to FIG. 2).

As shown in step S1010, the at least one processor (e.g., processor 2 of FIG. 1) may generate, for each sub-model (e.g., sub-models 11A, 21A, and 31A, as shown in FIG. 2), a sub-graph representation (e.g., sub-graph representations 12A, 22A, and 32A, as shown in FIG. 2), having said structural elements (e.g., structural elements 11A′, 21A′, and 31A′, as shown in FIG. 2) and parameters thereof (e.g., parameters 11A″, 21A″, and 31A″, as shown in FIG. 2) represented as semantic triples (e.g., semantic triples 12A′, 22A′, and 32A′, as shown in FIG. 2). Step S1010 may be carried out by model-to-graph/graph-to-model converters 12, 22, and 32 (as described with reference to FIG. 2).

As shown in step S1015, the at least one processor (e.g., processor 2 of FIG. 1) may analyze said semantic triples (e.g., semantic triples 12A′, 22A′, and 32A′, as shown in FIG. 2) taken from different sub-graph representations (e.g., sub-graph representations 12A, 22A, and 32A, as shown in FIG. 2) to detect interrelations therebetween. Step S1015 may be carried out by semantic enrichment module 42, and, in particular, by current condition generating module 43 and constraint condition generating module 44 (as described with reference to FIG. 2).

As shown in step S1020, the at least one processor (e.g., processor 2 of FIG. 1) may instantiate semantic connections (e.g., semantic relationship node 201 and edges 208′ and 209′, as shown in FIG. 3) between the generated sub-graph representations (e.g., sub-graph representations 12A, 22A, and 32A, as shown in FIGS. 2 and 3), based on detected interrelations, thereby obtaining a meta-graph representation (e.g., meta-graph representation 42A, as shown in FIGS. 2 and 3) of a model of the object. Step S1020 may be carried out by semantic enrichment module 42, and, in particular, by current condition generating module 43 and constraint condition generating module 44 (as described with reference to FIG. 2).

As shown in step S1025, the at least one processor (e.g., processor 2 of FIG. 1) may develop the model of the object, based on the obtained meta-graph representation (e.g., meta-graph representation 42A, as shown in FIGS. 2 and 3). Step S1025 may be carried out by change propagation and version control module 46 (as described with reference to FIG. 2).

As can be seen from the provided description, the claimed invention represents a system and method of federated computer-aided modeling which provide an improvement of the respective technological field by mitigating the abovementioned interoperability problem, improving collaboration efficiency, increasing compatibility and consistency across discipline-specific sub-models, thereby reducing federated modeling processes duration, in particular, reducing the number of redundant manual and semi-manual operations required to bring into line sub-models created by technical specialists of different disciplines.

Furthermore, as can be seen, the present invention represents federated computer-aided modelling techniques, which provide an explicit machine-understandable description of inter-model (or inter-sub-model) relationships, thereby enabling intelligent functions that substantially facilitate the modelling process. In particular, the present invention provides a description of semantics connecting structural elements of separate sub-models, thereby providing tools for querying and inferring design-intent aspects at inter-sub-model and inter-domain levels.

Unless explicitly stated, the method embodiments described herein are not constrained to a particular order or sequence. Furthermore, all formulas described herein are intended as examples only and other or different formulas may be used. Additionally, some of the described method embodiments or elements thereof may occur or be performed at the same point in time.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

Various embodiments have been presented. Each of these embodiments may of course include features from other embodiments presented, and embodiments not specifically described may include various features described herein.

1. A method of federated computer-aided modeling of an object, by at least one processor, the method comprising:
obtaining a plurality of sub-models, complementary representing the object, wherein each sub-model consists of one or more structural elements defined by parameters thereof;
for each sub-model, generating a sub-graph representation, having said structural elements and parameters thereof represented as semantic triples;
analyzing said semantic triples taken from different sub-graph representations to detect interrelations therebetween;
instantiating semantic connections between the generated sub-graph representations, based on detected interrelations, thereby obtaining a meta-graph representation of a model of the object; and
developing the model of the object, based on the obtained meta-graph representation.

2. The method of claim 1, wherein said sub-models of the plurality of sub-models represent different design domains.

3. The method of claim 1, wherein said federated computer-aided modeling is Building information modeling (BIM) and the object is a built object.

4. The method of claim 1, wherein at least one of said semantic triples comprises elements selected from the list consisting of: (i) at least one node data element corresponding to said one or more structural elements or semantic relationships therebetween, (ii) at least one edge data element corresponding to semantic relationships between said node data elements, and (iii) at least one attribute data element representing an attribute associated with said at least one node data element or at least one edge data element.

5. The method of claim 4, wherein said semantic relationships represent at least one of (i) spatial relationships; and (ii) functional relationships.

6. The method of claim 5, wherein said spatial relationships comprise at least one of (i) topological relationships; (ii) distance relationships; and (iii) directional relationships.

7. The method of claim 1, wherein said parameters are selected from the list consisting of (i) parameters defining geometrical characteristics of a respective structural element; (ii) parameters defining a position of the respective structural element within a respective sub-model; (iii) parameters defining an orientation of the respective structural element within the respective sub-model; (iv) parameters defining a material type of the respective structural element; (v) parameters defining a color of the respective structural element; (vi) parameters defining a functional characteristic of the respective structural element; and (vii) parameters defining a pattern of the respective structural element.

8. The method of claim 1, wherein instantiating semantic connections between the generated sub-graph representations comprises:
for at least one pair of node data elements corresponding to the structural elements and taken from different sub-graph representations, instantiating:
(i) at least one node data element corresponding to semantic relationships between said at least one pair of node data elements; and
(ii) a pair of edge data elements each connecting a respective node data element of the pair of node data elements with said at least one node data element corresponding to semantic relationships therebetween, and indicating whether the respective node data element of the pair of the pair of node data elements forms an object-predicate or a subject-predicate type of relationships with said at least one node data element corresponding to semantic relationships.

9. The method of claim 8, wherein said at least one node data element corresponding to semantic relationships comprises: (i) at least one node data element representing a current condition of said semantic relationships between the pair of node data elements corresponding to the structural elements; and (ii) at least one node data element representing a constraint condition for semantic relationships between the pair of node data elements corresponding to the structural elements.

10. The method of claim 9, wherein
a first sub-model of the plurality of sub-models comprises a first structural element of the one or more structural elements, the first structural element corresponding to a first node data element of the pair of node data elements;
a second sub-model of the plurality of sub-models comprises a second structural element of the one or more structural elements, the second structural element corresponding to a second node data element of the pair of node data elements; and
wherein developing the model of the object comprises:
applying an alteration to at least one parameter of the first structural element;
modifying the first node data element corresponding to said alteration;
modifying the at least one node data element representing the current condition of said semantic relationships between the pair of node data elements, according to the modified first node data element;
determining an incompliance of said current condition with said constraint condition; and
further developing the model, based on the incompliance.

11. The method of claim 10, wherein developing the model, based on the incompliance, comprises providing a message indicating the incompliance via a user interface (UI) of a respective computer-aided modelling tool for developing at least one of the first sub-model and the second sub-model.

12. The method of claim 10, wherein further developing the model, based on the incompliance, comprises providing a respective alteration to at least one parameter of the second structural element to fix the incompliance, or providing a respective alteration to at least one parameter of the first structural element to fix the incompliance.

13. The method of claim 9, wherein said at least one node data element representing the current condition is associated with at least one attribute data element representing an attribute selected from the list consisting of: (i) a topology type enumerated value; (ii) an offset value indicating distance between respective structural elements; and (iii) a binary value indicating presence of a contact between the respective structural elements.

14. The method of claim 9, wherein said at least one node data element representing the constraint condition is associated with at least one attribute data element representing an attribute selected from the list consisting of: (i) a physical connection type enumerated value taken from a list of predefined physical connection types; (ii) a constraint direction indication value indicating direction in space in which the constraint condition is applied; and (iii) a constraint threshold value defining the constraint condition; (iv) a comparison operator associated with the constraint threshold value and further defining the constraint condition; and (v) a constraint status value indicating whether the constraint condition is fulfilled or violated.

15. The method of claim 9, wherein instantiating semantic connections between the generated sub-graph representations further comprises inferring a respectively pretrained machine-learning (ML)-based model on the generated sub-graph representations to instantiate semantic connections therebetween.

16. The method of claim 15, further comprising receiving a plurality of training samples, each comprising a training plurality of sub-graph representations, associated with a respective training meta-graph representation connecting said training plurality of sub-graph representations; and
applying the plurality of training samples to train the ML-based model to calculate a target meta-graph representation based on a target plurality of sub-graph representations.

17. The method of claim 16, wherein each of training meta-graph representations comprises a training node data element representing an example of a current condition of semantic relationships between specific node data elements corresponding to the structural elements taken from different sub-graph representations of the training plurality of sub-graph representations; and
wherein training the ML-based model comprises training the ML-based model to instantiate a target node data element representing a target constraint condition for semantic relationships between specific node data elements corresponding to the structural elements.

18. The method of claim 9, wherein each of said structural elements is associated with a specific structural element type; and
wherein instantiating the at least one node data element representing the constraint condition is further performed by selecting a predefined constraint condition for a respective pair of the specific structural element types.

19. The method of claim 9, wherein
a first sub-model of the plurality of sub-models comprises a first structural element, the first structural element corresponding to a first node data element of the pair of node data elements, the first node data element being in an original version;
a second sub-model of the plurality of sub-models comprises a second structural element, the second structural element corresponding to a second node data element of the pair of node data elements; and
wherein developing the model of the object comprises:
applying an alteration to at least one parameter of the first structural element;
instantiating an alternative version of the first node data element, according to said alteration;
instantiating an alternative version of a node data element representing the current condition of semantic relationships between the pair of node data elements, based on the alternative version of the first node data element;
providing a selection between said original and alternative versions via a user interface (UI) of a respective computer-aided modelling tool of the second sub-model.

20. A system for federated computer-aided modeling of an object, the system comprising: a non-transitory memory device, wherein modules of instruction code are stored, and at least one processor associated with the memory device, and configured to execute the modules of instruction code, whereupon execution of said modules of instruction code, the at least one processor is configured to:
obtain a plurality of sub-models, complementary representing the object, wherein each sub-model consists of one or more structural elements defined by parameters thereof;
for each sub-model, generate a sub-graph representation, having said structural elements and parameters thereof represented as semantic triples;
analyze said semantic triples taken from different sub-graph representations to detect interrelations therebetween;
instantiate semantic connections between the generated sub-graph representations, based on detected interrelations, thereby obtaining a meta-graph representation of a federated model of the object; and
develop the model of the object, based on the obtained meta-graph representation.
